(19) United States
(12) Patent Application Publication
(10) Pub. No.: US 2012/0080776 A1
(43) Pub. Date: Apr. 5, 2012

(54) SEMICONDUCTOR DEVICE AND METHOD OF MANUFACTURING THE SAME

(75) Inventors: Akira KOMATSU, Ishikawa-ken (JP); Hitoshi TSUJI, Ishikawa-ken (JP); Kaori FUSE, Ishikawa-ken (JP)

(73) Assignee: Kabushiki Kaisha Toshiba, Tokyo (JP)

(21) Appl. No.: 13/249,094

(22) Filed: Sep. 29, 2011

(30) Foreign Application Priority Data
Sep. 30, 2010 (JP) P2010-223207

(51) Int. Cl. H01L 29/02; H01L 21/28

(52) U.S. Cl. 257/622; 438/597; 257/E29.002; 257/E21.158

(57) ABSTRACT

A semiconductor device includes: element formation regions each including a cell region where a semiconductor element is formed, a termination trench region; and a dicing line region including a groove separating the element formation regions. The termination trench region includes four trenches surrounding four sides of the cell region. Two of the trenches extend longitudinally in parallel to an X direction and the other two trenches extend longitudinally in parallel to a Y direction perpendicular to the X direction. The termination trench region is perpendicularly in contact with longitudinal sides of the dicing line region while the trenches extending longitudinally in parallel to the X direction intersect the trenches extending longitudinally in parallel to the Y direction at four corners of the element formation region, while vertical sections of the termination trench region in a cross direction are opened in four side surfaces of the element formation region.

### CROSS-REFERENCE TO RELATED APPLICATIONS

This application is based upon and claims the benefit of priority from the prior Japanese Patent Application No. 2010-22307, filed on Sep. 30, 2010; the entire contents of which are incorporated herein by reference.

### BACKGROUND OF THE INVENTION

1. Field of the Invention

Embodiments of the invention relate to a structure of a termination trench for a semiconductor wafer, and to a method of manufacturing the semiconductor wafer.

2. Description of the Related Art

Transistor elements with a trench gate structure are used in power MOSFETs (also known as insulated gate field effect transistors) and power IGBTs (insulated gate bipolar transistors), which are kinds of switching elements with a high voltage and a large current.

In a transistor element with a trench gate structure, a termination trench region surrounding a cell region is formed in a termination portion of an element formation region formed on a semiconductor wafer. A low-permittivity insulating material, such as poly silicon, is filled in an inside of the termination trench region extending from the surface of a body region to a drift region. The low-permittivity insulating material thus filled makes it possible to improve the avalanche breakdown voltage.

In a case where, however, the low-permittivity insulating material is filled by the spin coating method, the low-permittivity insulating material partially runs off along dicing lines that separate chip regions from each other. Consequently, the low-permittivity insulating material is not completely filled in the inside of the termination trench region and forms voids. The occurrence of such voids in the inside of the termination trench region poses a problem that the inside of the termination trench region is swollen, burst and damaged when the semiconductor wafer is thermally treated.

### BRIEF DESCRIPTION OF THE DRAWINGS

FIG. 1 is a plan view of a semiconductor wafer of a first embodiment.

FIG. 2 is a magnified plan view of a part of the semiconductor wafer of the first embodiment before the coating of an insulating film.

FIG. 3 is a three-dimensional sectional view of a part of the semiconductor wafer of the first embodiment.

FIGS. 4A to 4D are process drawings showing how the semiconductor wafer of the first embodiment is manufactured.

FIG. 5 is a magnified plan view of a portion of a semiconductor wafer of a second embodiment before the coating of an insulating film.

FIG. 6 is a plan view of a portion of the semiconductor wafer of the second embodiment which is coated with an insulating film.

### DETAILED DESCRIPTION

In an embodiment, a semiconductor device includes: element formation regions each including a cell region where a semiconductor element is formed, and a termination trench region; and a dicing line region including a groove separating the element formation regions from one another. The termination trench region includes four trenches surrounding four sides of the cell region, two of the four tranches extending longitudinally in parallel to an X direction, the other two of the four trenches extending longitudinally in parallel to a Y direction perpendicular to the X direction. The termination trench region is perpendicularly in contact with longitudinal sides of the dicing line region while the trenches extending longitudinally in to the X direction intersect the other trenches extending longitudinally in parallel to the Y direction at four corners of the element formation region, and while vertical sections of the termination trench region in a cross direction are opened in four side surfaces of the element formation region.

Embodiments of the invention are described below by referring to the drawings. In the following description, the same members are denoted by the same reference numerals, and explanations for such members are omitted whenever deemed possible.

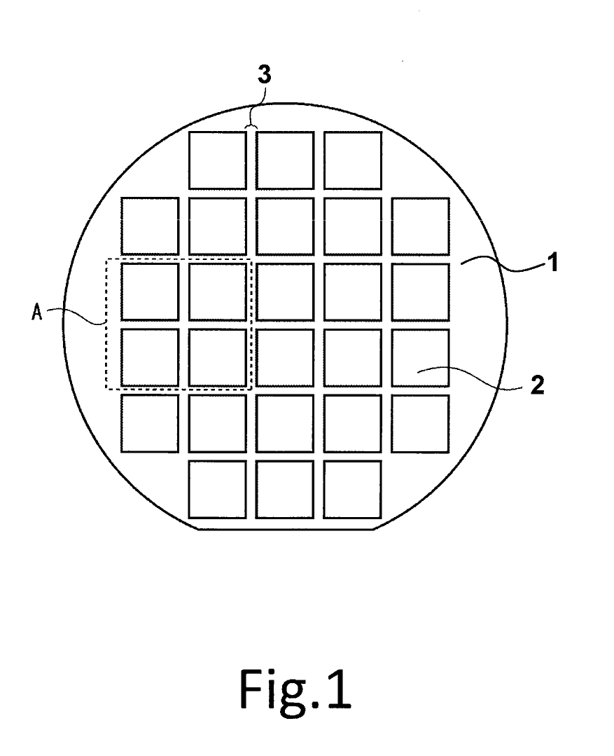

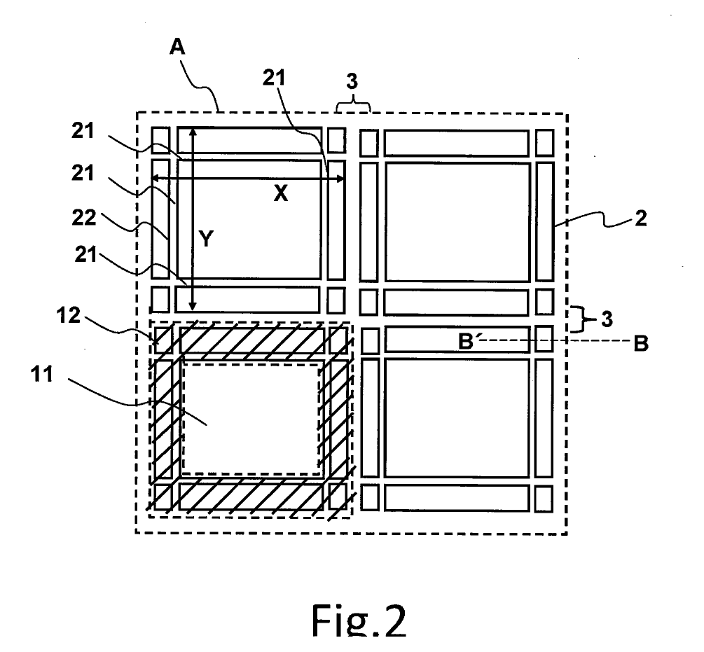

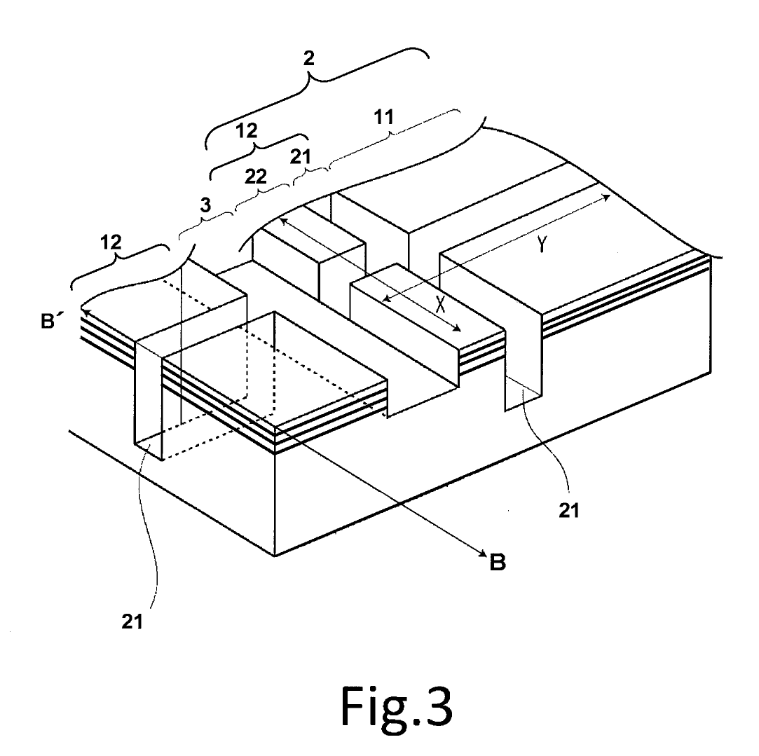

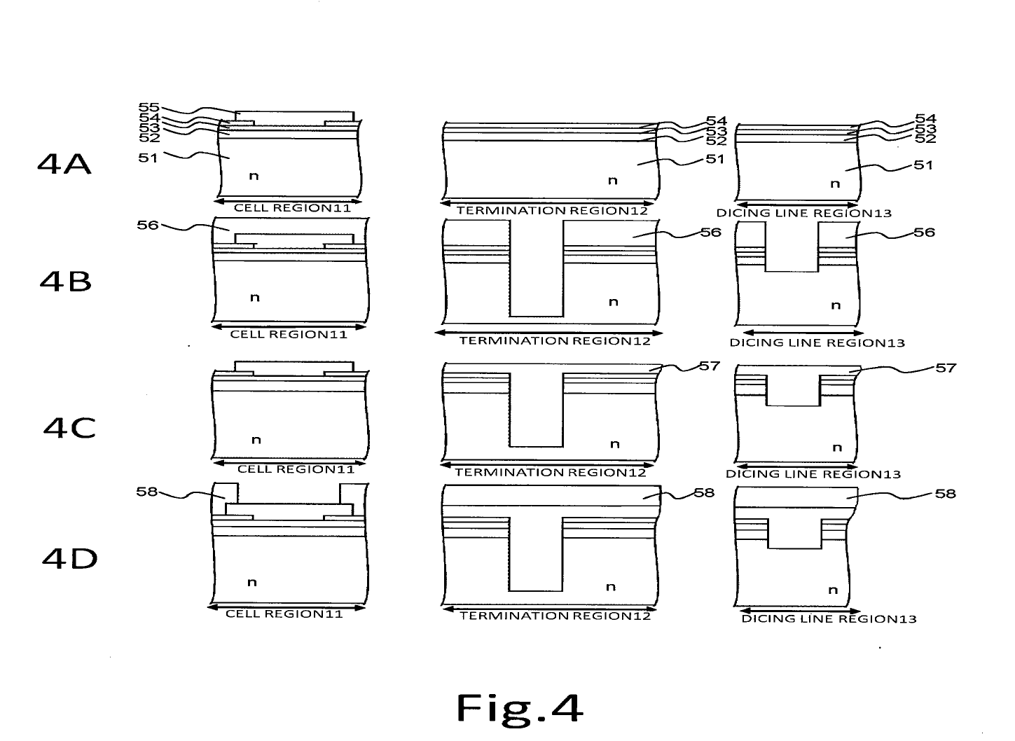

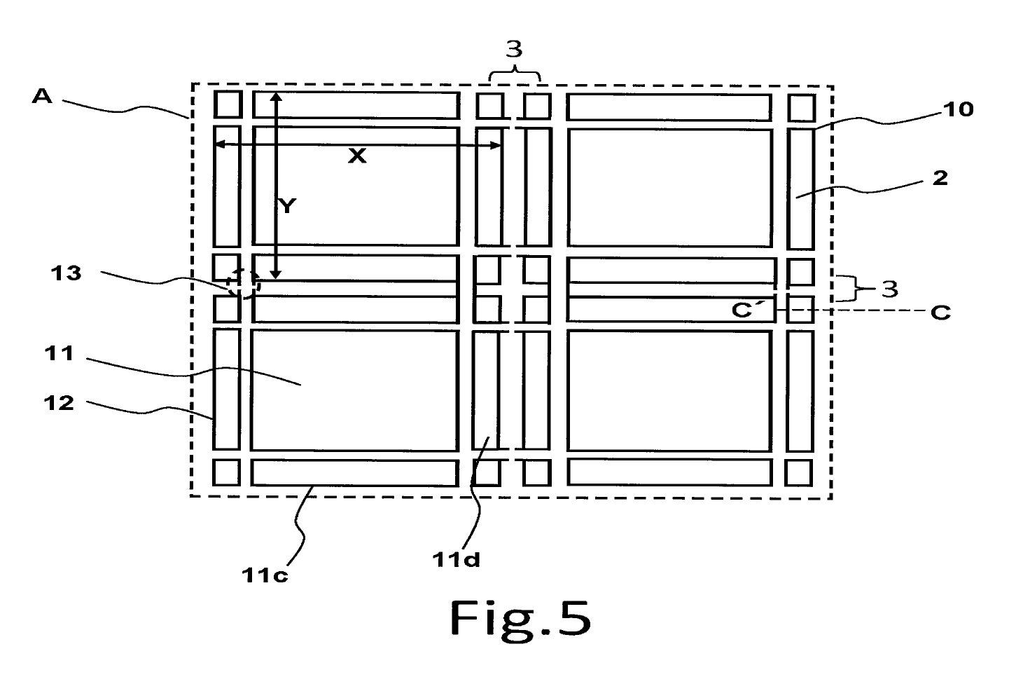

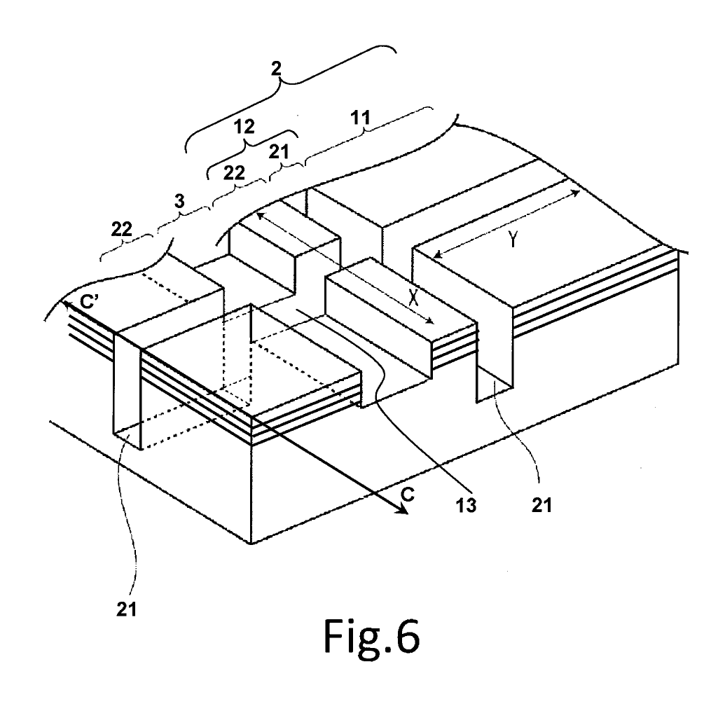

FIG. 1 is a plan view of a semiconductor wafer of a first embodiment. FIG. 2 is a magnified plan view of a portion of the semiconductor wafer of the first embodiment before the coating of an insulating film. FIG. 3 is a three-dimensional sectional view of a portion of the semiconductor wafer of the first embodiment. FIGS. 4A to 4D are process drawings showing how the semiconductor wafer of the first embodiment is manufactured. FIG. 5 is a magnified plan view of a portion of a semiconductor wafer of a second embodiment before the coating of an insulating film. FIG. 6 is a plan view of the semiconductor wafer of the second embodiment which is coated with an insulating film.

### First Embodiment

As FIG. 1 shows, a semiconductor wafer 1 made of silicon or the like where semiconductor elements are formed includes multiple element formation regions 2 and dicing line regions 3. Semiconductor elements are formed in the respective element formation regions 2. After the element formation regions 2 are separated from one another, each element formation region becomes a semiconductor chip. A dicing line region 3 is provided between each neighboring two of the element formation regions 2. Cuts are made in the semiconductor wafer 1 along the dicing line regions 3. Multiple semiconductor chips are formed by splitting the semiconductor wafer 1 along the cuts. There are various methods to make such cuts. For instance, diamond cutters are used (a scribe method); portions of the surface of the wafer are melted by laser irradiation (a laser method); and cutting grooves are formed by rotating blades at high speed (a dicing saw method).

Multiple wiring layers (multi-layer wirings) and the like, which are not illustrated), are formed on the semiconductor wafer 1 where the semiconductor elements are formed. The multiple wiring layers and insulating films are alternately stacked on one another, so that the wiring layers are covered with the insulating films. As described later, the stacked insulating films cover both the element formation regions 2 and the dicing line regions 3.

FIG. 2 is a magnified plan view of a portion (hereinafter referred to as an “A region”) of the semiconductor wafer 1 before the insulating films are formed. The A region represents a planar region A of the semiconductor wafer 1 surrounded by a dashed line in FIG. 1. Each element formation region 2 is roughly divided into two regions. Specifically, each element formation region 2 includes: a cell region 11; and a termination region 12 (indicated with oblique lines) formed to surround four sides of the cell regions 11 in terminal end portions of the element formation region 2.

In the cell region 11, for instance, an n+ type epitaxial layer as a semiconductor layer and a p+ type base layer as a portion of a planar MOSFET may be formed on and over an n+ type layer as a semiconductor substrate. In the cell region 11, however, any kind of element, not particularly limited, may be formed.

As shown in FIG. 2, a termination trench portion 21 with a width of approximately 20 μm to 50 μm is formed in the termination region 12 to surround the four sides of the cell region 11 along the border between the cell region 11 and the termination region 12. The termination trench portion 21 pierces a termination portion 22 in two perpendicular directions. To put it differently, the termination trench portion 21 in each cell region 11 includes: two trenches extending longitudinally in parallel to the X direction; and two trenches extending longitudinally in parallel to the Y direction. These four trenches surround the four sides of the cell region 11 while interesting with each other at the four corners of the element formation region 2.

FIG. 3 is a three-dimensional sectional view of the semiconductor wafer 1, viewed from above, before the insulating film is coated. FIG. 3 is a sectional view of the semiconductor wafer 1 taken along the B-B′ line in the magnified plan view shown in FIG. 2. As FIG. 3 shows, two different element formation regions 2 are adjacent to each other across one dicing line region 3. In the first embodiment, the termination trench portions 21 of the adjacent element formation regions 2 are not connected to each other across the dicing line region 3. Each cross section of the termination trench portion 21 in a cross direction is opened while being in contact with a longitudinal side of the dicing line region 3 at right angles, and thereby is partially opened to and partially occluded by the dicing line region 3.

In addition, as shown in FIG. 3, the depth of the dicing line region 3 is formed to be less than that of the termination trench portion 21. For instance, the termination trench portion 21 is formed to have a depth of 50 μm while the dicing line region 3 is formed to have a depth of 50 μm or less. Accordingly, when the insulating film is dropped and spin-coated onto the semiconductor wafer 1, the insulating film is firstly spread into the dicing line regions 3 that are shallower than the termination trench portions 21, and then spread into the termination trench portions 21 that are deeper than the dicing line regions 3. Because each termination trench portion 21 is formed in a shape entirely surrounding the cell region 11, the insulating film can be spread evenly due to a capillary action without forming voids in the termination trench portion 21.

Description is given below of a method of manufacturing the semiconductor wafer 1 of the first embodiment.

FIGS. 4A to 4B are diagrams illustrating a method of manufacturing the regions of the semiconductor wafer 1, i.e., the cell regions 11, the termination regions 12, and the dicing line regions 3.

In the cell regions 11, the termination regions 12 and the dicing line regions 3, as shown in FIG. 4A, a p well (base region) 52 for a trench gate element is selectively formed, and a p well 53 for a planar gate element is selectively formed in a surface layer portion of an n type semiconductor substrate (drain region) 51. Thereafter, a SiO₂ film 54, which includes openings corresponding to the cell regions 11 and the dicing line regions 3, is formed over the semiconductor wafer 1. In this process, in the cell regions 11, the SiO₂ film 54 is etched, and then a metal 55 is deposited with a thickness of approximately 3.8 μm, for example.

As FIG. 4B shows, a resist 56 is deposited with a thickness of 0.6 μm to 3.8 μm approximately on the structure shown in FIG. 4A. Then, the termination regions 12 are processed by RIE (reactive ion etching) to etch the SiO2 film 54 and to form the structure of the termination trench portions 21. Each termination trench portion 21 is formed, for instance, to have an opening width of 20 μm to 100 μm and a depth of approximately 50 μm. Simultaneously, the dicing line regions 3 are formed in a manner similar to that of the termination trench portions 21. Note that, as described earlier, it is desirable that the dicing line regions 3 should be shallower than the termination trench portions 21, and have an opening width of approximately 50 μm to 60 μm and a depth of 50 μm or less.

Subsequently, the insulating film 57 is spin-coated on the entire semiconductor wafer 1, and thereby is embedded in the termination trench portions 21, as FIG. 4C shows. The insulating film 57 mainly used in the first embodiment is a low-permittivity insulating film (commonly known as a low-k film). As the low-permittivity insulating film, widely used is a fluorine-added silicon oxide film that is a material for a semiconductor device, and has a lower specific permittivity (3.4 to 3.7) than the specific permittivity (3.9 to 4.1) of silicon oxide film. Specifically, for the spin coating, it is desirable to use an insulating film made of any one of PTFE (poly tetra fluoro ethylene with a specific permittivity of 2.1), PAE (poly aryl ether with a specific permittivity of 2.7 to 2.9), porous PAE (with a specific permittivity of 2.0 to 2.2), and BCB (benzo cyclo butane with a specific permittivity of 2.6 to 3.3).

Then, as FIG. 4D shows, a passivation film 58 may be applied to protect the semiconductor wafer 1. If, however, the insulating film 57 used in this case functions as a protection film, no passivation film 58 needs to be applied.

Since, as described above, each termination region 12 is provided with the termination trench portion 21 formed to surround the four sides of the cell region 11 while communicating with the dicing line region 3, the insulating film 57 spread along the dicing line region 3 is more easily filled in the inside of the termination trench portion 21 with the help of the capillary action.

Note that the capillary action is largely affected by the viscosity of a material. In a case where, for example, the opening width is less than 50 μm, the use of a material with a viscosity of 1000 Cp or less makes it possible to form a void-free embedded film. In a case where the opening width is 50 μm or larger, the use of a material with a viscosity of up to 20000 Cp makes it possible to obtain a satisfactory embedded film. The capillary action can be made more effective, if the termination trench portions 21 and the dicing line regions 3 are formed with the same trench dimensions, or if the dicing line regions 3 are formed larger in trench dimensions than the termination trench portions 21.

### Second Embodiment

FIG. 5 is a plan view of a semiconductor wafer 1 of a second embodiment, and illustrates the semiconductor wafer 1 before the coating with the insulating film. This second embodiment differs from the first embodiment in that: each termination trench portion 21 is extended in its longitudinal direction to the termination trench portion 21 of the adjacent element formation region 2 through the dicing line region 3; and thereby the termination trench portions 21 extend in the longitudinal direction through the dicing line region 3 so that the termination trench portions 21 can be connected to each other, as shown in FIG. 5.

FIG. 6 is a three-dimensional sectional view of a portion of the semiconductor wafer 1 of the second embodiment before an insulating film is applied. FIG. 6 shows a section of the portion of the semiconductor wafer 1 taken along the line C-C′ in FIG. 5. As FIG. 6 shows, a trench (hereinafter, referred to as an extended trench) 13 is formed in the dicing line region 3 and on the extension of the termination trench portion 21 in the longitudinal direction. The extended trench 13 is connected to the termination trench portion 21 of the adjacent element formation region 2, which is located on the extension of the extended trench 13 in the longitudinal direction. In addition, as FIG. 6 shows, the termination trench portion 21 and the extended trench 13 are formed deeper than the dicing line region 3. For instance, the termination trench portion 21 and the extended trench 13 are formed with a depth of 50 μm, while the dicing line region 3 is formed with a depth of 50 μm or less. Accordingly, when the insulating film is dropped and spin-coated onto the semiconductor wafer 1, the insulating film is firstly spread into the dicing line regions 3 that are shallower than the termination trench portions 21, and then spread into the termination trench portions 21 and the extended trenches 13 that are deeper than the dicing line regions 3. Because the termination trench portion 21 is formed in a shape entirely surrounding the cell regions 11 and communicating with the adjacent element formation regions 2 via the extended trenches 13, the insulating film can be spread evenly due to a capillary action without forming voids in the termination trench portions 21.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

1. A semiconductor device comprising:
a plurality of element formation regions each including
a cell region where a semiconductor element is formed, and
a termination trench region formed to include four trenches surrounding four sides of the cell region, two of the four trenches extending longitudinally in parallel to an X direction, the other two of the four trenches extending longitudinally in parallel to a Y direction perpendicular to the X direction; and
a dicing line region including a groove separating the element formation regions from one another, wherein
the termination trench region is perpendicularly in contact with longitudinal sides of the dicing line region while the trenches extending longitudinally in parallel to the X direction intersect the trenches extending longitudinally in parallel to the Y direction at four corners of the element formation region, and while vertical sections of the termination trench region in a cross direction are opened in four side surfaces of the element formation region.

2. The semiconductor device according to claim 1, wherein the groove of the dicing line region is shallower than any of the trenches formed in the termination trench region.

3. The semiconductor device according to claim 1, wherein the termination trench region includes an extended trench region on its extension in the longitudinal direction, the extended trench region formed to perpendicularly intersect the longitudinal sides of the dicing line region, and to be connected to the termination trench region of an adjacent element formation region.

4. A method of manufacturing a semiconductor device comprising the steps of:
stacking a base region, a well region, and an oxide film in this order on a surface layer portion of a semiconductor substrate;
etching the oxide film and depositing a metal in a cell region where a semiconductor element is to be formed;
forming a resist pattern on the semiconductor substrate, and etching a termination trench region and a dicing region to remove the oxide film therefrom, and to make a depth of the termination trench region deeper than that of a groove formed in the dicing region; and
spin-coating an insulating film all over the semiconductor substrate, and thereby embedding the insulating film in the termination trench region.
